(19) United States
(12) Patent Application Publication
(10) Pub. No.: US 2015/0295575 A1
(43) Pub. Date: Oct. 15, 2015

(54) GATE DRIVING CIRCUIT AND GATE DRIVING METHOD

(71) Applicant: Shenzhen China Star Optoelectronics Technology Co. Ltd., Shenzhen, Guangdong (CN)

(72) Inventor: Jihshiang Lee, Shenzhen (CN)

(73) Assignee: Shenzhen China Star Optoelectronics Technology Co. Ltd., Shenzhen, Guangdong (CN)

(21) Appl. No.: 14/384,613

(22) PCT Filed: Jul. 18, 2014
(86) PCT No.: PCT/CN2014/082500

§ 371 Date: Sep. 11, 2014

(30) Foreign Application Priority Data
Apr. 15, 2014 (CN) 201410151819.8

(51) Int. Cl. H03K 17/693; H03K 17/687

(52) U.S. Cl. CPC H03K 17/693; H03K 17/6872; H03K 2217/0054

(57) ABSTRACT

The present invention provides a gate driving circuit and a method thereof. The gate driving circuit comprises: a gate driving module (2 or 2′) and a plurality of multiplexer modules (4 or 4′), and the multiplexer modules (4 or 4′) are electrically connected to corresponding signal output ends (20 or 20′), and comprises a low voltage level input end (VGL or VGL′) and a first, a second, a third signal output ends (43, 44, 45 or 43′, 44′, 45′), electrically connected to a tri-gate structure panel, and the multiplexer modules (4 or 4′) control on/off of the first, the second, the third signal output ends (43, 44, 45 or 43′, 44′, 45′) and the low voltage level input end (VGL or VGL′) or the corresponding signal output ends (20 or 20′). The present invention also provides a corresponding gate driving method. The gate driving circuit and the gate driving method of the present invention can enormously reduce the amount of the tri-gate mode gate driving elements and the layout area in the panel borders.

### FIELD OF THE INVENTION

The present invention relates to a display skill field, and more particularly to a gate driving circuit and a gate driving method.

### BACKGROUND OF THE INVENTION

GOA (Gate Driver on Array) skill is to integrate the TFT (Thin Film Transistor) of a gate driving circuit on the array substrate and to eliminate the integrated circuit part of the gate driving circuit located outside the array substrate. Accordingly, two aspects of material cost and process is considered to reduce the manufacture cost of the productions. GOA skill is a common gate driving circuit skill used in a present TFT-LCD (Thin Film Transistor-Liquid Crystal Display). The manufacture process is simple and provides great application possibilities. The functions of the GOA circuit mainly comprises: the present gate line outputs a high level signal with charging the capacitor of the shift register unit by using the high level signal outputted from the previous gate line, and then reset is achieved by using the high level signal outputted from the next gate line.

Please refer to FIG. 1, which is a structural diagram of a panel having a GOA coordinating with tri-gate structure according to prior art. The GOA according to prior art mainly composed by several shift register units. Each shift register unit corresponds to one gate line, which the output end is employed for driving the pixel area of the display panel. That is, the whole gate driver corresponds to G₁, G₂, . . . G₃ₙ gate scan lines, and the pixel area comprises a plurality of pixels array arranged by using the tri-gate design (3-dimension transistor), and each pixel unit comprises three colors, R, G, B. and the source driver outputs data signals to respective pixels through the data lines S₁, S₂, . . . Sₘ. The tri-gate (3-dimension transistor) skill is a kind of special stack up structure. Fin-tailplane compositions are added on three faces of conducting channel of the Tri-gates to rule out the surplus heat. With the high combination of gate isolation and the strained silicon, longer battery life and better performance can be possible for the mobile devices. With the panel utilizing the GOA coordinating with the tri-gate structure, the number of the gate scan lines can be increased three times. Thereby, the number of the data lines of source driver can be reduced. The cost of the source driver can be diminished. With the combination of the tri-gate skill and the GOA technology, the objective of single chip can be realized.

However, one cell of the GOA generally comprises several TFTs and capacitors, such as 7T2C. The capacitors occupy a certain area in layout. Under circumstance that it coordinates with the panel of the tri-gate structure, the cell number of the whole GOA becomes three times of the original design. The layout area in the panel borders becomes too large.

On the other hand, the multiplexer technology is urging to transmit multiple signals in one channel for efficiently using the channel line because the bandwidth and the capability of the transmission media usually exceeds the requirement of transmitting single signals in the data communication system or in the computer network system. By conducting the multiplexer technology, multiple signals can be combined to be transmitted in one physical channel line. The installation and maintenance fees could be tremendously saved for a long distance transmission.

### SUMMARY OF THE INVENTION

An objective of the present invention is to provide a gate driving circuit, comprising multiplexer modules capable of reducing the layout area in the panel borders and the amount of the tri-gate mode gate driving elements under normal condition of driving the gate lines.

Another objective of the present invention is to provide a gate driving method capable of reducing the layout area in the panel borders and the amount of the tri-gate mode gate driving elements under normal condition of driving the gate lines.

For realizing the aforesaid objective, the present invention provides a gate driving circuit, comprising: a gate driving module having a plurality of signal output ends and a plurality of multiplexer modules, and each of the multiplexer modules is electrically connected to a corresponding signal output end, and comprises a low voltage level input end and a first, a second, a third signal output ends, electrically connected to a tri-gate structure panel, and each of the multiplexer modules controls on/off of the first, the second, the third signal output ends and the low voltage level input end or the corresponding signal output end; as driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end.

The gate driving module is a GOA module.

The multiplexer module comprises a first multiplexer unit, a second multiplexer unit and a third multiplexer unit;

the first multiplexer unit comprises a first transistor and a second transistor, and the first transistor has a first gate, a first source and a first drain, and the second transistor has a second gate, a second source and a second drain, and the first source is electrically connected to the signal output end of the gate driving module, and the first gate is electrically connected to the second gate, and the second drain is electrically connected to the low voltage level input end, and the first drain is electrically connected to the second source and the first signal output end;

the second multiplexer unit comprises a third transistor and a fourth transistor, and the third transistor has a third gate, a third source and a third drain, and the fourth transistor has a fourth gate, a fourth source and a fourth drain, and the third source is electrically connected to the signal output end of the gate driving module, and the third gate is electrically connected to the fourth gate, and the fourth drain is electrically connected to the low voltage level input end, and the third drain is electrically connected to the fourth source and the second signal output end;

the third multiplexer unit comprises a fifth transistor and a sixth transistor, and the fifth transistor has a fifth gate, a fifth source and a fifth drain, and the sixth transistor has a sixth gate, a sixth source and a sixth drain, and the fifth source is electrically connected to the signal output end of the gate driving module, and the fifth gate is electrically connected to the sixth gate, and the sixth drain is electrically connected to the low voltage level input end, and the fifth drain is electrically connected to the sixth source and the third signal output end;

the first transistor, the third transistor and the fifth transistor are N type MOS transistors, and the second transistor, the fourth transistor and the sixth transistor are P type MOS transistors.

As driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end, and a control signal EN_R is inputted to the first gate and the second gate, and a control signal EN_G is inputted to the third gate and the fourth gate, and a control signal EN_B is inputted to the fifth gate and the sixth gate.

The first multiplexer unit, the second multiplexer unit and the third multiplexer unit are Low Temperature Poly Silicon TFTs.

The multiplexer module comprises a first multiplexer unit, a second multiplexer unit and a third multiplexer unit;

the first multiplexer unit comprises a first transistor and a second transistor, and the first transistor has a first gate, a first source and a first drain, and the second transistor has a second gate, a second source and a second drain, and the first source is electrically connected to the signal output end of the gate driving module, and the first gate is electrically connected to the second gate, and the second drain is electrically connected to the low voltage level input end, and the first drain is electrically connected to the second source and the first signal output end;

the second multiplexer unit comprises a third transistor and a fourth transistor, and the third transistor has a third gate, a third source and a third drain, and the fourth transistor has a fourth gate, a fourth source and a fourth drain, and the third source is electrically connected to the signal output end of the gate driving module, and the third gate is electrically connected to the fourth gate, and the fourth drain is electrically connected to the low voltage level input end, and the third drain is electrically connected to the fourth source and the second signal output end;

the third multiplexer unit comprises a fifth transistor and a sixth transistor, and the fifth transistor has a fifth gate, a fifth source and a fifth drain, and the sixth transistor has a sixth gate, a sixth source and a sixth drain, and the fifth source is electrically connected to the signal output end of the gate driving module, and the fifth gate is electrically connected to the sixth gate, and the sixth drain is electrically connected to the low voltage level input end, and the fifth drain is electrically connected to the sixth source and the third signal output end;

the first transistor, the second transistor, the third transistor, the fourth transistor, the fifth transistor and the sixth transistor are all N type MOS transistors.

As driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end, and a control signal EN_R is applied to the first gate, and a control signal EN_G is applied to the third gate, and a control signal EN_B is applied to the fifth gate, and reverse control signals, EN_R, EN_G, EN_B are control signals, EN_R_N, EN_G_N, EN_B_N respectively which are respectively applied to the second gate, the fourth gate and the sixth gate.

The first multiplexer unit, the second multiplexer unit and the third multiplexer unit are Low Temperature Poly Silicon TFTs.

The present invention further provides an gate driving circuit, comprising: a gate driving module having a plurality of signal output ends and a plurality of multiplexer modules, and each of the multiplexer modules is electrically connected to a corresponding signal output end, and comprises a low voltage level input end and a first, a second, a third signal output ends, electrically connected to a tri-gate structure panel, and each of the multiplexer modules controls on/off of the first, the second, the third signal output ends and the low voltage level input end or the corresponding signal output end; as driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end;

wherein the gate driving module is a GOA module;

wherein the multiplexer module comprises a first multiplexer unit, a second multiplexer unit and a third multiplexer unit;

the first multiplexer unit comprises a first transistor and a second transistor, and the first transistor has a first gate, a first source and a first drain, and the second transistor has a second gate, a second source and a second drain, and the first source is electrically connected to the signal output end of the gate driving module, and the first gate is electrically connected to the second gate, and the second drain is electrically connected to the low voltage level input end, and the first drain is electrically connected to the second source and the first signal output end;

the second multiplexer unit comprises a third transistor and a fourth transistor, and the third transistor has a third gate, a third source and a third drain, and the fourth transistor has a fourth gate, a fourth source and a fourth drain, and the third source is electrically connected to the signal output end of the gate driving module, and the third gate is electrically connected to the fourth gate, and the fourth drain is electrically connected to the low voltage level input end, and the third drain is electrically connected to the fourth source and the second signal output end;

the third multiplexer unit comprises a fifth transistor and a sixth transistor, and the fifth transistor has a fifth gate, a fifth source and a fifth drain, and the sixth transistor has a sixth gate, a sixth source and a sixth drain, and the fifth source is electrically connected to the signal output end of the gate driving module, and the fifth gate is electrically connected to the sixth gate, and the sixth drain is electrically connected to the low voltage level input end, and the fifth drain is electrically connected to the sixth source and the third signal output end;

the first transistor, the third transistor and the fifth transistor are N type MOS transistors, and the second transistor, the fourth transistor and the sixth transistor are P type MOS transistors.

As driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end, and a control signal EN_R is inputted to the first gate and the second gate, and a control signal EN_G is inputted to the third gate and the fourth gate, and a control signal EN_B is inputted to the fifth gate and the sixth gate.

The first multiplexer unit, the second multiplexer unit and the third multiplexer unit are Low Temperature Poly Silicon TFTs.

The present invention further provides a gate driving method, comprising:

step 100, providing a gate driving module having a plurality of signal output ends and a plurality of multiplexer modules, and each of the multiplexer modules comprises a low voltage level input end and a first, a second, a third signal output ends;

step 110, electrically connecting the multiplexer modules to the corresponding signal output ends;

step 120, electrically connecting multiplexer modules to a tri-gate structure panel via the first, the second, the third signal output ends;

step 130, controlling the first, the second, the third signal output ends alternately to be electrically conducted with the corresponding signal output ends by the multiplexer modules as driving the tri-gate structure panel;

step 140, controlling the first, the second, the third signal output ends alternately to be electrically conducted with the corresponding signal output ends by the multiplexer modules as driving the tri-gate structure panel.

The gate driving module is a GOA module.

The benefits of the present invention are: in the gate driving circuit and the gate driving method according to the present invention, the multiplexer module is applied in a gate driving circuit coordinating with a tri-gate structure panel. Accordingly, the panel having the gate driving circuit coordinating with a tri-gate structure can reduce the layout area in the panel borders and still normally drive the gate lines.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution, as well as beneficial advantages, of the present invention will be apparent from the following detailed description of an embodiment of the present invention, with reference to the attached drawings.

In drawings,

FIG. 1 is a structural diagram of a panel having a GOA coordinating with tri-gate structure according to prior art;

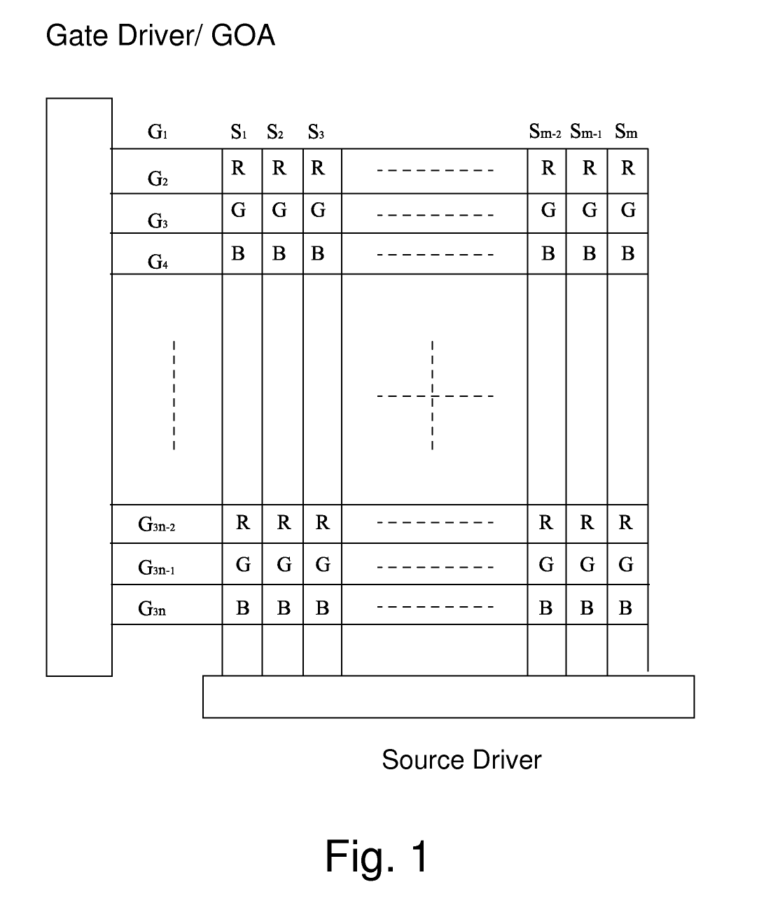

FIG. 2 is a sequence diagram of a gate driving circuit according to the present invention;

FIG. 3 is a circuit diagram of a gate driving circuit according to the first embodiment of the present invention;

FIG. 4 is a circuit diagram of a gate driving circuit according to the second embodiment of the present invention.

### DETAILED DESCRIPTION OF PREFERRED EMBODIMENTS

Embodiments of the present invention are described in detail with the technical matters, structural features, achieved objects, and effects with reference to the accompanying drawings as follows.

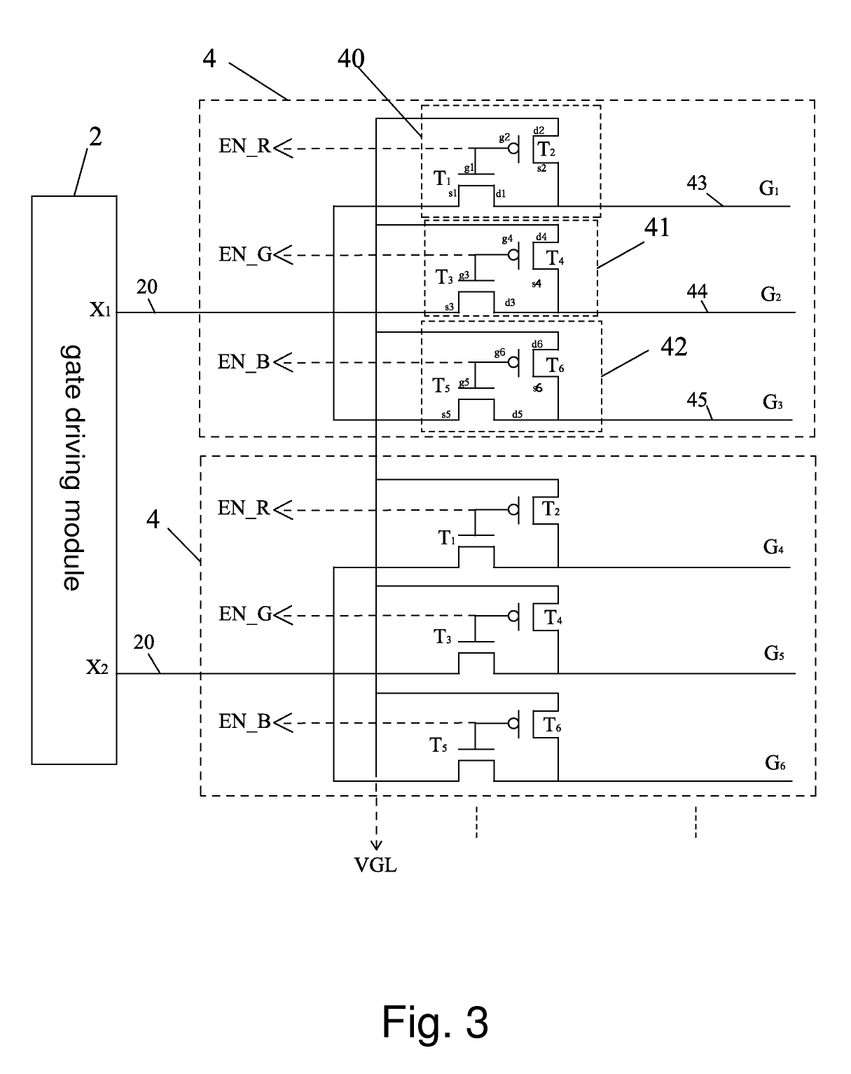

Please refer to FIG. 3, which is a circuit diagram of a gate driving circuit according to the first embodiment of the present invention. The present invention provides a gate driving circuit, comprising: a gate driving module 2 and a plurality of multiplexer module 4 electrically connected to gate driving module 2 and applied in a tri-gate structure panel. The gate driving module 2 comprises a plurality of signal output ends 20; the gate driving module 2 can be a GOA module;

the multiplexer module 4 comprises a voltage level input end VGL, a first, a second and a third multiplexer units 40, 41, 42 and a first, a second, a third signal output ends 43, 44, 45;

each of the multiplexer modules 4 has three control signals, respectively corresponding to the first, the second and the third multiplexer units 40, 41, 42;

each of the signal output ends 20 is electrically coupled to the first, the second, the third signal output ends 43, 44, 45 of the multiplexer module 4;

in this embodiment, the first multiplexer module 4 is illustrated for explanation. The multiplexer module 4 comprises a voltage level input end VGL, a first, a second and a third multiplexer units 40, 41, 42 and a first, a second, a third signal output ends 43, 44, 45; the first, the second, the third signal output ends 43, 44, 45 of the multiplexer module 4 is electrically coupled to the signal output end 20 of the gate driving module 2;

the first multiplexer unit 40 comprises a first transistor T1 and a second transistor T2, and the first transistor T1 has a first gate g1, a first source s1 and a first drain d1, and the second transistor T2 has a second gate g2, a second source s2 and a second drain d2, and the first source s1 is electrically connected to the signal output end 20 of the gate driving module 2, and the first gate g1 is electrically connected to the second gate g2, and the second drain d2 is externally connected to the low voltage level input end VGL for controlling the thin film transistor (TFT) to be off, and the first drain d1 is electrically connected to the second source s2 and the first signal output end 43 of the multiplexer module 4.

The second multiplexer unit 41 comprises a third transistor T3 and a fourth transistor T4, and the third transistor T3 has a third gate g3, a third source s3 and a third drain d3, and the fourth transistor T4 has a fourth gate g4, a fourth source s4 and a fourth drain d4, and the third source s3 is electrically connected to the signal output end 20 of the gate driving module 2, and the third gate g3 is electrically connected to the fourth gate g4, and the fourth drain d4 is externally connected to the low voltage level input end VGL for controlling the thin film transistor to be off, and the third drain d3 is electrically connected to the fourth source s4 and the second signal output end 44 of the multiplexer module 4.

The third multiplexer unit 42 comprises a fifth transistor T5 and a sixth transistor T6, and the fifth transistor T5 has a fifth gate g5, a fifth source s5 and a fifth drain d5, and the sixth transistor T6 has a sixth gate g6, a sixth source s6 and a sixth drain d6, and the fifth source s5 is electrically connected to the signal output end 20 of the gate driving module 2, and the fifth gate g5 is electrically connected to the sixth gate g6, and the sixth drain d6 is externally connected to the low voltage level input end VGL for controlling the thin film transistor to be off, and the fifth drain d5 is electrically connected to the sixth source s6 and the third signal output end 45 of the multiplexer module 4.

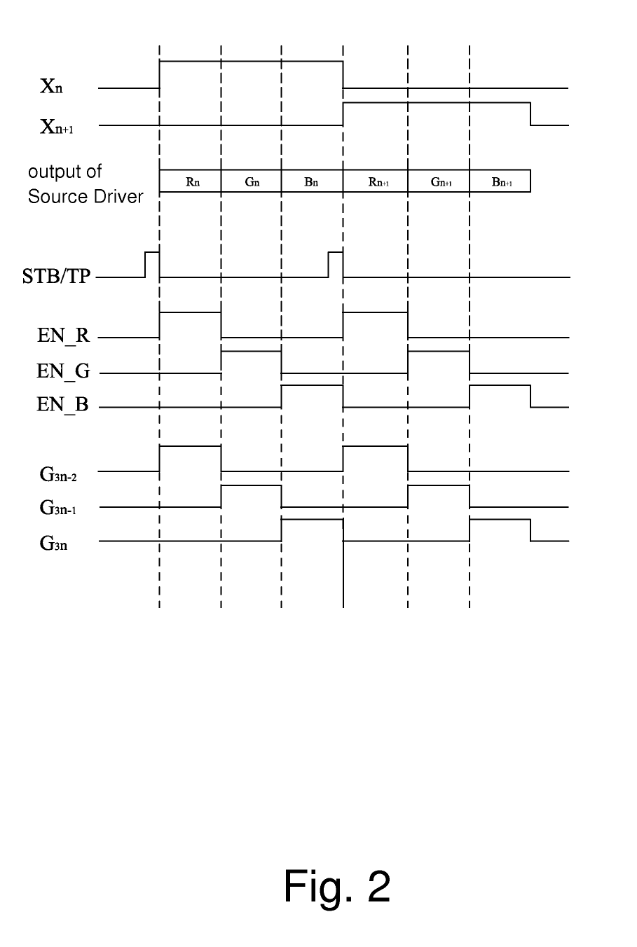

In this embodiment, the first transistor T1, the third transistor T3 and the fifth transistor T5 of the first, the second and the third multiplexer units 40, 41 and 42 are N type MOS transistors, and the second transistor T2, the fourth transistor T4 and the sixth transistor T6 are P type MOS transistors. The first, the second and the third multiplexer units 40, 41 and 42 can be manufactured by Low Temperature Poly Silicon (LTPS) processes. Each of the multiplexer modules 4 has three control signals, respectively and correspondingly applied to the first gate g1 and the second gate g2, the third gate g3 and the fourth gate g4, the fifth gate g5 and the sixth gate g6, which respectively are EN_R (an enable signal of controlling the red pixel), EN_G (an enable signal of controlling the green pixel), EN_B (an enable signal of controlling the blue pixel). The signals, EN_R, ENG and EN_B can be generated by a present source IC. As shown in FIG. 2, the start signal (STB or TP) of the present source IC can be utilized for analyzing the starting point of every set of RGB signals. The starting point of every RGB signals can control to be triggered by a counter. The waveforms of STB/TP, EN_R, EN_G and EN_B can be indicated as shown in FIG. 2. The present invention can be utilized in a GOA circuit. These three signal lines, EN_R, EN_G and EN_B can be added on the glass substrate.

The first, the second, the third signal output ends 43, 44, 45 of each multiplexer module 4 utilizes multiplexer unit (mux) to perform the switch. The amount of the multiplexer module required for the whole circuit will be M/3 if the number of the signal output ends of the multiplexer module is M. The output of every GOA unit can correspond to three scan lines and use the mux to perform the switch. That is, an output Xₙ of the GOA unit shown in FIG. 2 can be switched to three scan lines, G₃ₙ₋₂, G₃ₙ₋₁ and G₃ₙ with the circuit shown in FIG. 3. If the required amount of the gate scan lines is N, the number of the GOA unit can be N/3 according to the present invention. Correspondingly, the number of the GOA units can be decreased and the layout area in the panel borders can be reduced.

Please refer to FIG. 2 in conjunction with FIG. 3. FIG. 2 is a sequence diagram of a gate driving circuit according to the present invention. If the signal output ends of the gate driving module 2 are arranged with a certain sequence, the first, the second, the third signal output ends of the multiplexer module applied in a tri-gate structure panel are also arranged correspondingly. N represents the sequence of the arrangement. Therefore, Xₙ and Xₙ₊₁ in FIG. 2 correspond to the signal output ends, such as X₁ and X₂ of the gate driving module in FIG. 3; G₃ₙ₋₂, G₃ₙ₋₁, G₃ₙ in FIG. 2 correspond to the first, the second, the third signal output ends of module are in FIG. 3. The output signals G₁, G₂, . . . G₆ are employed to drive the corresponding pixels Rₙ, Gₙ, Bₙ and etc. The working principle of the first embodiment according to the present invention is: the enable signal EN_R is illustrated for description. The first transistor T1 and the second transistor T2 simultaneously receive the enable signal EN_R, and the second source s2 of the second transistor T2 is connected to the first drain d1 of the first transistor T1, and the second drain d2 of the second transistor T2 is externally connected to the low voltage level input end VGL. When the enable signal EN_R is at the high voltage level, the first transistor T1 is on, the first drain d1 of the first transistor T1 is at the high voltage level. At this time, the gate voltage VGS of the second transistor T2 is at the low voltage level, in the off state, and the first signal output end 43 is normally scanned and conducted. At the next time slot, the enable signal EN_G is activated, and the high voltage level is still inputted to the signal output end 20 correspondingly. At this time, the enable signal EN_R is at the low voltage level, and the first transistor T1 is off, and the gate voltage VGS of the second transistor T2 is at the negative high voltage level, and the second transistor T2 is switched to be in a on state, and now the first signal output end 43 is at the VGL low voltage level, and no scan signal.

In a similar way, as the enable signal is EN_G, the third transistor T3 and the fourth transistor T4 simultaneously receive the enable signal EN_G, and the fourth source s4 of the fourth transistor T4 is connected to the third drain d3 of the third transistor T3, and the fourth drain d4 of the fourth transistor T4 is externally connected to the low voltage level input end VGL. When the enable signal EN_G is at the high voltage level, the third transistor T3 is on, the third drain d3 of the third transistor T3 is at the high voltage level. At this time, the gate voltage VGS of the fourth transistor T4 is at the low voltage level, in the off state, and the second signal output end 44 is normally scanned and conducted. At the next time slot, the enable signal EN_B is activated, and the high voltage level is still inputted to the signal output end 20 correspondingly. At this time, the enable signal EN_G is at the low voltage level, and the third transistor T3 is off, and the gate voltage VGS of the fourth transistor T4 is at the negative high voltage level, and the fourth transistor T4 is switched to be in a on state, and now the second signal output end 44 is at the VGL low voltage level, and no scan signal.

As the enable signal is EN_B, the fifth transistor T5 and the sixth transistor T6 simultaneously receive the enable signal EN_B, and the sixth source s6 of the sixth transistor T6 is connected to the fifth drain d5 of the fifth transistor T5, and the sixth drain d6 of the sixth transistor T6 is externally connected to the low voltage level input end VGL. When the enable signal EN_B is at the high voltage level, the fifth transistor T5 is on, the fifth drain d5 of the fifth transistor T5 is at the high voltage level. At this time, the gate voltage VGS of the sixth transistor T6 is at the low voltage level, in the off state, and the third signal output end 45 is normally scanned and conducted. At the next time slot, the enable signal EN_R is activated, and the high voltage level is still inputted to the signal output end 20 correspondingly. At this time, the enable signal EN_B is at the low voltage level, and the fifth transistor T5 is off, and the gate voltage VGS of the sixth transistor T6 is at the negative high voltage level, and the sixth transistor T6 is switched to be in a on state, and now the third signal output end 45 is at the VGL low voltage level, and no scan signal.

Next, for the scan lines outputted from every GOA unit and the multiplexer modules applied in the tri-gate structure panel, the aforesaid procedure can be implemented periodically.

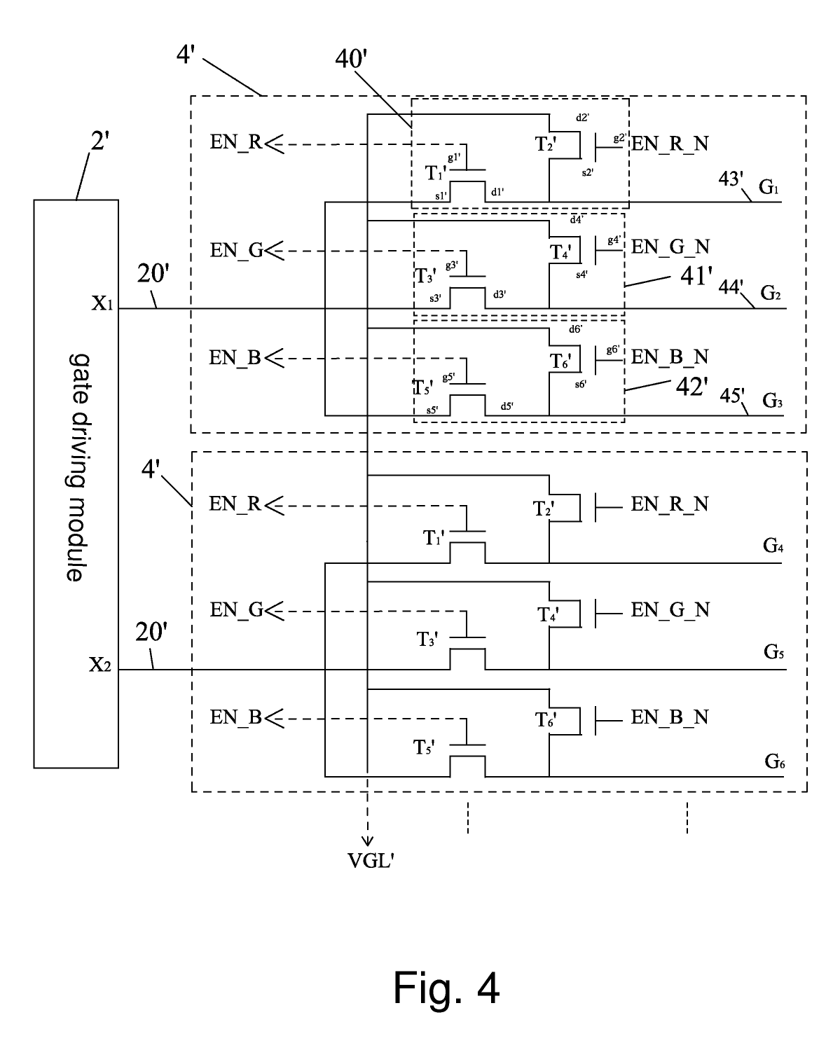

Please refer to FIG. 4 in conjunction with FIG. 2. FIG. 4 is a circuit diagram of a gate driving circuit according to the second embodiment of the present invention. If the signal output ends are arranged with a certain sequence, the first, the second, the third signal output ends of the multiplexer module applied in a tri-gate structure panel are also arranged correspondingly. N represents the sequence of the arrangement. Therefore, Xₙ and Xₙ₊₁ in FIG. 2 correspond to the signal output ends, such as X₁ and X₂ of the gate driving module in FIG. 4; G₃ₙ₋₂, G₃ₙ₋₁, G₃ₙ in FIG. 2 correspond to the first, the second, the third signal output ends of module are in FIG. 4. This embodiment comprises: a gate driving module 2′ and a plurality of multiplexer module 4′ electrically connected to gate driving module 2′ and applied in a tri-gate structure panel. The gate driving module 2′ comprises a plurality of signal output ends 20′;

the multiplexer module 4 comprises a voltage level input end VGL, a first, a second and a third multiplexer units 40, 41, 42 and a first, a second, a third signal output ends 43, 44, 45;

each of the multiplexer modules 4′ has three control signals and three reverse control signals, respectively corresponding to the first, the second and the third multiplexer units 40′, 41′, 42′;

each of the signal output ends 20′ is electrically coupled to the first, the second, the third signal output ends 43′, 44′, 45′ of the multiplexer module 4′;

in this embodiment, the first multiplexer module 4′ applied in a tri-gate structure panel is illustrated for explanation. The multiplexer module 4′ comprises a voltage level input end VGL′, a first, a second and a third multiplexer units 40′, 41′, 42′ and a first, a second, a third signal output ends 43′, 44′, 45′; the first, the second, the third signal output ends 43′, 44′, 45′ of the multiplexer module 4′ is electrically coupled to the signal output end 20′ of the gate driving module 2′;

the first multiplexer unit 40′ comprises a first transistor T1′ and a second transistor T2′, and the first transistor T1′ has a first gate g1′, a first source s1′ and a first drain d1′, and the second transistor T2′ has a second gate g2′, a second source s2′ and a second drain d2′, and the first source s1′ is electrically connected to the signal output end 20′ of the gate driving module 2′, and the first gate g1′ is electrically connected to the second gate g2′, and the second drain d2′ is externally connected to the low voltage level input end VGL′ for controlling the thin film transistor to be off, and the first drain d1′ is electrically connected to the second source s2′ and the first signal output end 43′ of the multiplexer module 4′.

The second multiplexer unit 41′ comprises a third transistor T3′ and a fourth transistor T4′, and the third transistor T3′ has a third gate g3′, a third source s3′ and a third drain d3′, and the fourth transistor T4′ has a fourth gate g4′, a fourth source s4′ and a fourth drain d4′, and the third source s3′ is electrically connected to the signal output end 20′ of the gate driving module 2′, and the third gate g3′ is electrically connected to the fourth gate g4′, and the fourth drain d4′ is externally connected to the low voltage level input end VGL′ for controlling the thin film transistor to be off, and the third drain d3′ is electrically connected to the fourth source s4′ and the second signal output end 44′ of the multiplexer module 4′.

The third multiplexer unit 42′ comprises a fifth transistor T5′ and a sixth transistor T6′, and the fifth transistor T5′ has a fifth gate g5′, a fifth source s5′ and a fifth drain d5′, and the sixth transistor T6′ has a sixth gate g6′, a sixth source s6′ and a sixth drain d6′, and the fifth source s5′ is electrically connected to the signal output end 20′ of the gate driving module 2′, and the fifth gate g5′ is electrically connected to the sixth gate g6′, and the sixth drain d6′ is externally connected to the low voltage level input end VGL′ for controlling the thin film transistor to be off, and the fifth drain d5′ is electrically connected to the sixth source s6 and the third signal output end 45′ of the multiplexer module 4′.

In this embodiment, the first transistor T1′, the second transistor T2′, the third transistor T3′, the fourth transistor T4′, the fifth transistor T5′ and the sixth transistor T6′ are all N type MOS transistors. Each of the multiplexer modules 44′ has three control signals and three reverse control signals, and the three control signals are correspondingly applied to the first gate g1′, the third gate g3′ and the fifth gate g5′, which respectively are EN_R (an enable signal of controlling the red pixel), EN_G (an enable signal of controlling the green pixel), EN_B (an enable signal of controlling the blue pixel). The three reverse control signals are correspondingly applied to the first gate g2′, the third gate g4′ and the fifth gate g6′, which respectively are EN_R_N (an enable signal of reversely controlling the red pixel), EN_G_N (an enable signal of reversely controlling the green pixel), EN_B_N (an enable signal of reversely controlling the blue pixel). The signals, EN_R, EN_G and EN_B can be generated by a present source IC and correspondingly the EN_R_N, EN_G_N, EN_B_N can be generated. The present invention is utilized in a GOA circuit, these six signal lines, EN_R, EN_G, EN_B, EN_R_N, EN_G_N and EN_B_N can be added on the glass substrate. The first, the second and the third multiplexer units 40′, 41′ and 42′ can be manufactured by Low Temperature Poly Silicon (LTPS) processes.

The working principle of this embodiment is the same as the first embodiment. The repeated description is omitted here. The person who is skilled in this field can understand that the source and the drain of the NMOS and the PMOS are interchangeable. The annotations of the transistors in FIG. 3 and FIG. 4 are merely for illustrations. Moreover, the present invention applies the multiplexer skill to a GOA coordinating with the tri-gate structure panel, each set of the multiplexer comprises two transistors NMOS+PMOS or NMOS+NMOS, and the NMOS which is inputted from the GOA is employed for transmitting scan signals and the other PMOS (or NMOS) simultaneously receives VGL to control the TFT to be off. The sequence diagram shown in FIG. 2 is merely illustrated for explanation but not intended to be limiting of how to switch the one output of the GOA unit into three scan signals by the multiplexer according to the present invention.

According to the gate driving circuit of the present invention, the present invention further provides a gate driving method, mainly comprising:

step 100, providing a gate driving module having a plurality of signal output ends and a plurality of multiplexer modules, and each of the multiplexer modules comprises a low voltage level input end and a first, a second, a third signal output ends;

step 110, electrically connecting the multiplexer modules to the corresponding signal output ends;

step 120, electrically connecting multiplexer modules to a tri-gate structure panel via the first, the second, the third signal output ends;

step 130, controlling the first, the second, the third signal output ends alternately to be electrically conducted with the corresponding signal output ends by the multiplexer modules as driving the tri-gate structure panel;

step 140, controlling the first, the second, the third signal output ends, which are not electrically conducted with the corresponding signal output ends to be electrically conducted with the low voltage level input end by the multiplexer modules as driving the tri-gate structure panel.

The gate driving method can be understood according to the previous descriptions, FIG. 2, FIG. 3 and FIG. 4. The repeated descriptions are omitted here.

In conclusion, in the gate driving circuit and the gate driving method according to the present invention, the multiplexer module is applied in a gate driving circuit coordinating with a tri-gate structure panel. Accordingly, the panel having the gate driving circuit coordinating with a tri-gate structure can reduce the layout area in the panel borders and still normally drive the gate lines.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A gate driving circuit, comprising: a gate driving module having a plurality of signal output ends and a plurality of multiplexer modules, and each of the multiplexer modules is electrically connected to a corresponding signal output end, and comprises a low voltage level input end and a first, a second, a third signal output ends, electrically connected to a tri-gate structure panel, and each of the multiplexer modules controls on/off of the first, the second, the third signal output ends and the low voltage level input end or the corresponding signal output end; as driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end.

2. The gate driving circuit according to claim 1, wherein the gate driving module is a GOA module.

3. The gate driving circuit according to claim 2, wherein the multiplexer module comprises a first multiplexer unit, a second multiplexer unit and a third multiplexer unit;
the first multiplexer unit comprises a first transistor and a second transistor, and the first transistor has a first gate, a first source and a first drain, and the second transistor has a second gate, a second source and a second drain, and the first source is electrically connected to the signal output end of the gate driving module, and the first gate is electrically connected to the second gate, and the second drain is electrically connected to the low voltage level input end, and the first drain is electrically connected to the second source and the first signal output end;
the second multiplexer unit comprises a third transistor and a fourth transistor, and the third transistor has a third gate, a third source and a third drain, and the fourth transistor has a fourth gate, a fourth source and a fourth drain, and the third source is electrically connected to the signal output end of the gate driving module, and the third gate is electrically connected to the fourth gate, and the fourth drain is electrically connected to the low voltage level input end, and the third drain is electrically connected to the fourth source and the second signal output end;
the third multiplexer unit comprises a fifth transistor and a sixth transistor, and the fifth transistor has a fifth gate, a fifth source and a fifth drain, and the sixth transistor has a sixth gate, a sixth source and a sixth drain, and the fifth source is electrically connected to the signal output end of the gate driving module, and the fifth gate is electrically connected to the sixth gate, and the sixth drain is electrically connected to the low voltage level input end, and the fifth drain is electrically connected to the sixth source and the third signal output end;
the first transistor, the third transistor and the fifth transistor are N type MOS transistors, and the second transistor, the fourth transistor and the sixth transistor are P type MOS transistors.

4. The gate driving circuit according to claim 3, wherein as driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end, and a control signal EN_R is inputted to the first gate and the second gate, and a control signal EN_G is inputted to the third gate and the fourth gate, and a control signal EN_B is inputted to the fifth gate and the sixth gate.

5. The gate driving circuit according to claim 3, wherein the first multiplexer unit, the second multiplexer unit and the third multiplexer unit are Low Temperature Poly Silicon TFTs.

6. The gate driving circuit according to claim 1, wherein the multiplexer module comprises a first multiplexer unit, a second multiplexer unit and a third multiplexer unit;
the first multiplexer unit comprises a first transistor and a second transistor, and the first transistor has a first gate, a first source and a first drain, and the second transistor has a second gate, a second source and a second drain, and the first source is electrically connected to the signal output end of the gate driving module, and the first gate is electrically connected to the second gate, and the second drain is electrically connected to the low voltage level input end, and the first drain is electrically connected to the second source and the first signal output end;
the second multiplexer unit comprises a third transistor and a fourth transistor, and the third transistor has a third gate, a third source and a third drain, and the fourth transistor has a fourth gate, a fourth source and a fourth drain, and the third source is electrically connected to the signal output end of the gate driving module, and the third gate is electrically connected to the fourth gate, and the fourth drain is electrically connected to the low voltage level input end, and the third drain is electrically connected to the fourth source and the second signal output end;
the third multiplexer unit comprises a fifth transistor and a sixth transistor, and the fifth transistor has a fifth gate, a fifth source and a fifth drain, and the sixth transistor has a sixth gate, a sixth source and a sixth drain, and the fifth source is electrically connected to the signal output end of the gate driving module, and the fifth gate is electrically connected to the sixth gate, and the sixth drain is electrically connected to the low voltage level input end, and the fifth drain is electrically connected to the sixth source and the third signal output end;
the first transistor, the second transistor, the third transistor, the fourth transistor, the fifth transistor and the sixth transistor are all N type MOS transistors.

7. The gate driving circuit according to claim 6, wherein as driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end, and a control signal EN_R is applied to the first gate, and a control signal EN_G is applied to the third gate, and a control signal EN_B is applied to the fifth gate, and reverse control signals, EN_R, EN_G, EN_B are control signals, EN_R_N, EN_G_N, EN_B_N respectively which are respectively applied to the second gate, the fourth gate and the sixth gate.

8. The gate driving circuit according to claim 6, wherein the first multiplexer unit, the second multiplexer unit and the third multiplexer unit are Low Temperature Poly Silicon TFTs.

9. A gate driving circuit, comprising: a gate driving module having a plurality of signal output ends and a plurality of multiplexer modules, and each of the multiplexer modules is electrically connected to a corresponding signal output end, and comprises a low voltage level input end and a first, a second, a third signal output ends, electrically connected to a tri-gate structure panel, and each of the multiplexer modules controls on/off of the first, the second, the third signal output ends and the low voltage level input end or the corresponding signal output end; as driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end;
wherein the gate driving module is a GOA module;
wherein the multiplexer module comprises a first multiplexer unit, a second multiplexer unit and a third multiplexer unit;
the first multiplexer unit comprises a first transistor and a second transistor, and the first transistor has a first gate, a first source and a first drain, and the second transistor has a second gate, a second source and a second drain, and the first source is electrically connected to the signal output end of the gate driving module, and the first gate is electrically connected to the second gate, and the second drain is electrically connected to the low voltage level input end, and the first drain is electrically connected to the second source and the first signal output end;
the second multiplexer unit comprises a third transistor and a fourth transistor, and the third transistor has a third gate, a third source and a third drain, and the fourth transistor has a fourth gate, a fourth source and a fourth drain, and the third source is electrically connected to the signal output end of the gate driving module, and the third gate is electrically connected to the fourth gate, and the fourth drain is electrically connected to the low voltage level input end, and the third drain is electrically connected to the fourth source and the second signal output end;
the third multiplexer unit comprises a fifth transistor and a sixth transistor, and the fifth transistor has a fifth gate, a fifth source and a fifth drain, and the sixth transistor has a sixth gate, a sixth source and a sixth drain, and the fifth source is electrically connected to the signal output end of the gate driving module, and the fifth gate is electrically connected to the sixth gate, and the sixth drain is electrically connected to the low voltage level input end, and the fifth drain is electrically connected to the sixth source and the third signal output end;
the first transistor, the third transistor and the fifth transistor are N type MOS transistors, and the second transistor, the fourth transistor and the sixth transistor are P type MOS transistors.

10. The gate driving circuit according to claim 9, wherein as driving the tri-gate structure panel, the multiplexer modules control the first, the second, the third signal output ends alternately to be electrically conducted with the corresponding signal output ends, and controls the first, the second, the third signal output ends, which are not electrically conducted with the corresponding signal output ends to be electrically conducted with the low voltage level input end, and a control signal EN_R is inputted to the first gate and the second gate, and a control signal EN_G is inputted to the third gate and the fourth gate, and a control signal EN_B is inputted to the fifth gate and the sixth gate.

11. The gate driving circuit according to claim 9, wherein the first multiplexer unit, the second multiplexer unit and the third multiplexer unit are Low Temperature Poly Silicon TFTs.

12. A gate driving method, comprising:
step 100, providing a gate driving module having a plurality of signal output ends and a plurality of multiplexer modules, and each of the multiplexer modules comprises a low voltage level input end and a first, a second, a third signal output ends;
step 110, electrically connecting the multiplexer modules to the corresponding signal output ends;
step 120, electrically connecting multiplexer modules to a tri-gate structure panel via the first, the second, the third signal output ends;
step 130, controlling the first, the second, the third signal output ends alternately to be electrically conducted with the corresponding signal output ends by the multiplexer modules as driving the tri-gate structure panel;
step 140, controlling the first, the second, the third signal output ends, which are not electrically conducted with the corresponding signal output ends to be electrically conducted with the low voltage level input end by the multiplexer modules as driving the tri-gate structure panel.

13. The gate driving method according to claim 12, wherein the gate driving module is a GOA module.
